(19) United States
(12) Patent Application Publication
(10) Pub. No.: US 2025/0255166 A1
(43) Pub. Date: Aug. 7, 2025

(54) LIGHT-EMITTING ELEMENT AND METHOD FOR PRODUCING SAME, DISPLAY DEVICE, AND INK, AND METHOD FOR PRODUCING SAME

(71) Applicant: Sharp Display Technology Corporation, Kameyama City, Mie (JP)

(72) Inventors: Yang QU, Kameyama City, Mie (JP); Xiaohuan FU, Kameyama City, Mie (JP)

(21) Appl. No.: 18/855,854

(22) PCT Filed: May 30, 2022
(86) PCT No.: PCT/JP2022/021983

§ 371 Date: Oct. 10, 2024

(51) Int. Cl. H10K 71/13; B82Y 20/00; B82Y 40/00; C09D 11/037; C09D 11/106; C09D 11/322; C09D 11/50; C09K 11/55; H10K 50/165

(52) U.S. Cl. CPC H10K 71/135; C09D 11/037; C09D 11/106; C09D 11/322; C09D 11/50; C09K 11/55; H10K 50/165; B82Y 20/00; B82Y 40/00

(57) ABSTRACT

A light-emitting element includes a light-emitting layer, and an electrical function layer overlapping the light-emitting layer. The electrical function layer includes nanoparticles constituted by metal oxide nanoparticles and polyvinyl pyrrolidone.

### TECHNICAL FIELD

The disclosure relates to a light-emitting element and a method for manufacturing the same, a display device, and an ink and a method for manufacturing the same.

### BACKGROUND ART

Typically, various display devices including light-emitting elements have been developed. Examples of the light-emitting elements include organic light emitting diodes (OLEDs), and quantum dot light emitting diodes (QLEDs). The light-emitting element has a layered structure of a light-emitting layer and electrical function layers such as an electron transport layer, a hole injection layer, and a hole transport layer. As the electrical function layer, a layer constituted by nanoparticles of a metal oxide such as magnesium zinc oxide (MgZnO) is known (for example, see PTL 1).

### CITATION LIST

### Patent Literature

PTL 1: WO 2020/208671

### SUMMARY

### Technical Problem

The electrical function layer is typically produced by applying an ink by an ink-jet method or the like. For this reason, the ink containing a material of the electrical function layer is required to have excellent dispersion stability and coatability of the material. Metal oxide nanoparticles as dispersoids of the ink are selected according to performance in the electrical function layer, and an organic solvent that is an ink solvent serving as a dispersion medium of the ink is selected from the viewpoint of the coatability of the ink.

Depending on types of the ink solvent, dispersibility of the metal oxide nanoparticles may decrease. On the other hand, when the ink solvent is selected based on the dispersibility of the metal oxide nanoparticles, the coatability of the ink in manufacturing the electrical function layer may be insufficient in some cases. When the dispersibility or coatability of the ink is insufficient, uneven distribution of the metal oxide nanoparticles in the electrical function layer or uneven coating of the ink may occur, and luminous efficiency of the light-emitting element may decrease or uneven brightness may occur. As described above, in the related art, there is room for investigation from the viewpoint of uniformly dispersing the metal oxide nanoparticles in the ink regardless of the types of the metal oxide nanoparticles and the ink solvent.

An object of one aspect of the disclosure is to provide a technique that achieves a light-emitting element including an electrical function layer in which metal oxide nanoparticles are uniformly present.

### Solution to Problem

In order to solve the problems described above, according to the disclosure, there is provided a light-emitting element including a light-emitting layer, and an electrical function layer overlapping the light-emitting layer, wherein the electrical function layer contains nanoparticles constituted by metal oxide nanoparticles and polyvinyl pyrrolidone.

In addition, in order to solve the problems described above, according to the disclosure, there is provided a method for manufacturing a light-emitting element including applying an ink containing nanoparticles constituted by metal oxide nanoparticles and polyvinyl pyrrolidone and thus forming an electrical function layer as an upper layer of a light-emitting layer.

In addition, in order to solve the problems described above, according to the disclosure, there is provided an ink containing particles constituted by metal oxide nanoparticles and polyvinyl pyrrolidone, the particles being dispersed in a long-chain alcohol.

In addition, in order to solve the problems described above, according to the disclosure, there is provided a method for manufacturing an ink, including dispersing metal oxide nanoparticles in ethanol and thus preparing a first liquid, dispersing polyvinyl pyrrolidone in the first liquid and thus preparing a second liquid, evaporating the ethanol from the second liquid and thus forming a solid containing the metal oxide nanoparticles and the polyvinyl pyrrolidone, and bringing a long-chain alcohol into contact with the solid, diffusing the metal oxide nanoparticles together with the polyvinyl pyrrolidone in the long-chain alcohol, and thus manufacturing the ink according to claim 8.

### Advantageous Effects of Disclosure

One aspect of the disclosure can provide a technique that achieves a light-emitting element including an electrical function layer in which metal oxide nanoparticles are uniformly present.

### BRIEF DESCRIPTION OF DRAWINGS

FIG. 1 is a plan view schematically illustrating a configuration of a display device according to an embodiment of the disclosure.

FIG. 2 is a cross-sectional view schematically illustrating a configuration in a display region of the display device according to the embodiment of the disclosure.

FIG. 3 is a diagram schematically illustrating an example of a configuration of a light-emitting element according to an embodiment of the disclosure.

FIG. 4 is a diagram schematically illustrating an example of a manufacturing process from an ink to an electrical function layer according to an embodiment of the disclosure.

FIG. 5 is a flowchart illustrating an example of a process procedure of a method for manufacturing the ink according to an embodiment of the disclosure.

FIG. 6 is a flowchart illustrating an example of a distinctive process procedure of a method for manufacturing the light-emitting element according to an embodiment of the disclosure.

FIG. 7 is a diagram illustrating ink characteristics obtained in Example of the disclosure.

FIG. 8 is a diagram illustrating a photograph of an ink in Example of the disclosure.

### DESCRIPTION OF EMBODIMENTS

### Light-Emitting Element

According to an embodiment of the disclosure, a light-emitting element includes a light-emitting layer, and an electrical function layer. The light-emitting element has a structure in which function layers related to light emission are layered. Examples of the light-emitting element include an OLED and a QLED.

### Light-Emitting Layer

The light-emitting layer is a layer made of a light-emitting material. A color of light emitted from the light-emitting layer can be appropriately set to red, green, blue, or the like depending on the light-emitting material. A known material can be used as the light-emitting material, and the light-emitting layer can be produced by a known technique using the light-emitting material. The light-emitting layer may be a quantum dot (QD) layer.

The electrical function layer is a layer having a function of controlling movement of electrons or holes to the light-emitting layer. Examples of the electrical function layer configured to control the movement of electrons include an electron transport layer. Examples of the electrical function layer configured to control the movement of holes include a hole function layer. Examples of the hole function layer include a hole injection layer and a hole transport layer.

The electrical function layer is formed at a position overlapping the light-emitting layer. The electrical function layer may be disposed adjacent to the light-emitting layer in a layering direction, or may be disposed with another layer interposed between the electrical function layer and the light-emitting layer. The present embodiment is suitable for an electrical function layer to be produced by applying an ink to a light-emitting layer in manufacturing a light-emitting element. Therefore, the electrical function layer is preferably a layer disposed adjacent to the light-emitting layer in the layering direction, and is preferably a layer formed on the light-emitting layer in manufacturing the electrical function layer.

### Electrical Function Layer

The electrical function layer contains nanoparticles constituted by metal oxide nanoparticles and polyvinyl pyrrolidone. Hereinafter, the particles are also referred to as “composite material nanoparticles”.

Metal oxide nanoparticles are nanoparticles of a metal oxide. A nanoparticle is a particle having a nano-order particle size, and has a diameter equal to or less than 100 nm, for example.

The metal oxide of the metal oxide nanoparticles can be appropriately selected depending on a function of the electrical function layer. For example, when the electrical function layer is an electron transport layer, the metal oxide contains an n-type semiconductor. Examples of the n-type semiconductor include MgZnO, AlZnO, LiZnO, and ZnO.

Additionally, when the metal function layer is a hole function layer, the metal oxide contains a p-type semiconductor. Here, the hole function layer is a layer exhibiting a function for holes, and is, for example, a hole transport layer or a hole injection layer. Examples of the p-type semiconductor include NiO, CuO, and Cr₂O₃.

Note that the metal oxide nanoparticles may further contain other components such as other metal oxides as long as the effects of the disclosure can be obtained. The metal oxide nanoparticles may be a commercially available product, and the commercially available product may be in the form of powder or slurry. The slurry may contain a ligand that enhances dispersibility in the dispersion medium.

Poly Vinyl Pyrrolidone (PVP) may be supported on the surfaces of the metal oxide nanoparticles. The PVP may be a homopolymer or a copolymer as long as the effects of the disclosure can be obtained. From the viewpoint of handleability in preparing the composite material nanoparticles (manufacturing an ink, which will be described below), a molecular weight of the PVP is preferably 10000 to 130000 in terms of number-average molecular weight. Note that in the present specification, “a numerical value X to a numerical value Y” means a range being equal to or more than the numerical value X and equal to or less than the numerical value Y and including the numerical values at both ends thereof.

It is considered that in the composite material nanoparticles, the PVP is interposed between the metal oxide nanoparticles and the dispersion medium in the ink. That is, it is considered that the metal oxide nanoparticles become the composite material nanoparticles by having the PVP on the surface thereof, and as a result, are uniformly dispersed in the ink in the form of the composite material nanoparticles. The PVP may be coordinated to the surfaces of the metal oxide nanoparticles as ligands, or may be supported on the surfaces of the metal oxide nanoparticles by physical or chemical interaction. In this case, the composite material nanoparticle may be a nano-order core-shell particle including a metal oxide nanoparticle serving as a core particle and PVP serving as a shell.

The light-emitting element may further include another configuration other than the above-described layers as long as the effects of the disclosure are obtained. Examples of the other configuration include an electrode, an intermediate layer, a substrate, an insulating layer, and a bank.

### Display Device

A display device according to an embodiment of the disclosure includes a substrate, and the above-described light-emitting element disposed on the substrate. The display device of the disclosure can be configured in a manner the same as or similar to that of a known display device including a known light-emitting element except that the display device of the disclosure includes the above-described light-emitting element.

### Specific Aspects

Hereinafter, the display device and the light-emitting element of the disclosure will be described more specifically with reference to the drawings.

### Display Device

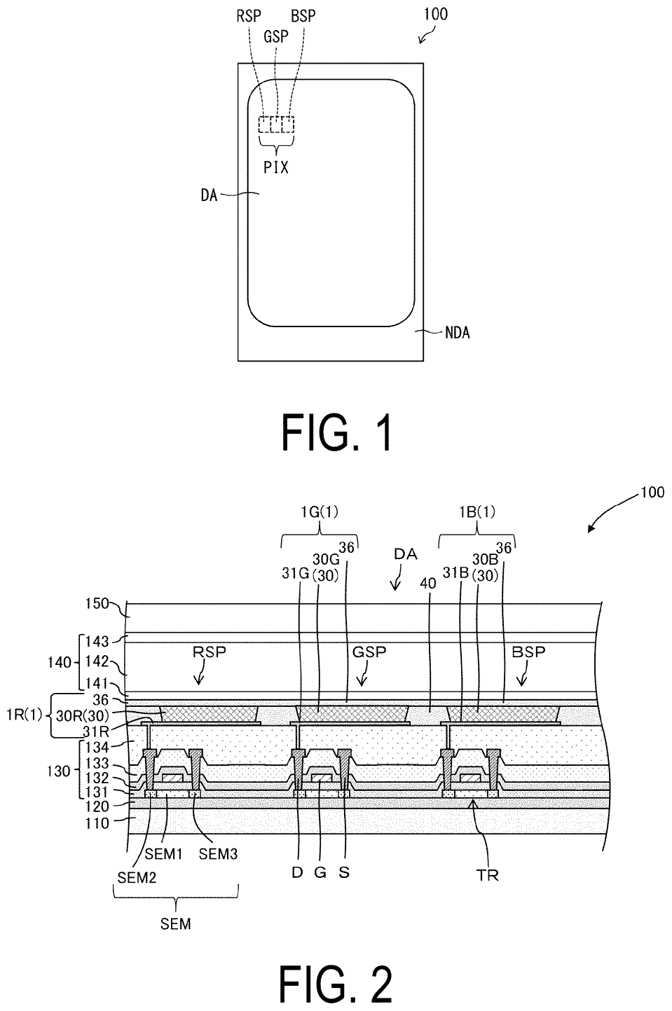

FIG. 1 is a plan view schematically illustrating a configuration of a display device according to an embodiment of the disclosure. A configuration of a light-emitting element in the display device will be described in more detail later, and first, a configuration of a display device will be described. As illustrated in FIG. 1, a display device 100 includes a frame region NDA and a display region DA. A plurality of pixels PIX are provided in the display region DA of the display device 100, and each pixel PIX includes a red subpixel RSP, a green subpixel GSP, and a blue subpixel BSP. The configuration of the pixel of the display device in the disclosure is not limited to the above-described configuration. In the display device of the disclosure, for example, one pixel PIX may further include a subpixel of another color in addition to the red subpixel RSP, the green subpixel GSP, and the blue subpixel BSP.

Note that in the present specification, configurations related to different colors among similar basic configurations are denoted by reference signs indicating colors added to a reference sign of the basic configurations. For example, a configuration related to red is denoted by R, a configuration related to green is denoted by G, and a configuration related to blue is denoted by B.

FIG. 2 is a cross-sectional view schematically illustrating a configuration in a display region of the display device according to the embodiment of the disclosure. As illustrated in FIG. 2, in the display region DA of the display device 100, a barrier layer 120, a thin film transistor layer 130 including transistors TR, a red light-emitting element 1R, a green light-emitting element 1G, a blue light-emitting element 1B, and a bank (transparent resin layer) 40, a sealing layer 140, and a function film 150 are provided on a substrate 110.

Note that a configuration in which the substrate 110, the barrier layer 120, and the thin film transistor layer 130 illustrated in FIG. 2 are provided in this order from the substrate 110 side is also referred to as an “active matrix substrate”.

The red subpixel RSP includes the red light-emitting element 1R, the green subpixel GSP includes the green light-emitting element 1G, and the blue subpixel BSP includes the blue light-emitting element 1B. The light-emitting element 1 of each color has a similar configuration except for a material of the light-emitting layer. Note that the configuration of the light-emitting element 1 will be described below.

The substrate 110 may be, for example, a resin substrate made of a resin material such as polyimide, or may be a glass substrate.

The barrier layer 120 is a layer that prevents foreign matters such as water and oxygen from entering the transistors TR, the red light-emitting element 1R, the green light-emitting element 1G, and the blue light-emitting element 1B. For example, the barrier layer 120 may include a silicon oxide film, a silicon nitride film, or a silicon oxynitride film formed by CVD, or a layered film thereof.

The thin film transistor layer 130 includes a portion including the transistor TR and a portion not including the transistor TR. At a portion other than the portions including the transistors TR in the thin film transistor layer 130, inorganic insulating films 131 to 133 and a flattening film 134 overlap each other in this order from the substrate 110 side. The portion including the transistor TR in the thin film transistor layer 130 includes a semiconductor film SEM, the inorganic insulating film 131, a gate electrode G, the inorganic insulating film 132, the inorganic insulating film 133, a source electrode S, a drain electrode D, and the flattening film 134. The semiconductor film SEM includes a drain region SEM2 and a source region SEM3 that are doped with an impurity such as P (phosphorus), and a channel region SEM1 between the drain region SEM2 and the source region SEM3.

The inorganic insulating films 131 to 133 can be constituted by, for example, a silicon oxide film, a silicon nitride film, or a silicon oxynitride film formed by CVD, or a layered film thereof. The inorganic insulating films 131 to 133 may be of the same type or different types. The flattening film 134 can be made of a coatable organic material such as polyimide and acrylic.

The semiconductor film SEM is made of, for example, low-temperature polysilicon (LTPS) or may be made of an oxide semiconductor (for example, an In—Ga—Zn—O based semiconductor). In the present embodiment, the transistor TR has, for example, a top gate structure. Note that in the disclosure, the transistor TR may have a bottom gate structure.

The gate electrode G, the source electrode S, and the drain electrode D are all constituted by a single layer film or a layered film of a metal. Examples of the metal include aluminum, tungsten, molybdenum, tantalum, chromium, titanium and copper.

Note that the thin film transistor layer 130 is provided with a control circuit including the transistors TR each of which controls a respective one of the red light-emitting element 1R, the green light-emitting element 1G, and the blue light-emitting element 1B that respectively correspond to the red subpixel RSP, the green subpixel GSP, and the blue subpixel BSP.

The red light-emitting element 1R includes a first electrode 31R that is an upper layer overlying the flattening film 134, a light-emitting function layer 30R including the red light-emitting layer, and a second electrode 36 in this order in the layering direction. Similarly, the green light-emitting element 1G includes a first electrode 31G that is an upper layer overlying the flattening film 134, a light-emitting function layer 30G including the green light-emitting layer, and the second electrode 36 in this order in the layering direction. The blue light-emitting element 1B also includes a first electrode 31B that is an upper layer overlying the flattening film 134, a light-emitting function layer 30B including the blue light-emitting layer, and the second electrode 36 in this order in the layering direction.

The sealing layer 140 is a transparent film and, for example, may be constituted by an inorganic sealing film 141 covering the second electrode 36, an organic film 142 that is an upper layer overlying the inorganic sealing film 141, and an inorganic sealing film 143 that is an upper layer overlying the organic film 142. The sealing layer 140 prevents foreign matters such as water and oxygen from penetrating into the red light-emitting element 1R, the green light-emitting element 1G, and the blue light-emitting element 1B.

Here, each of the inorganic sealing film 141 and the inorganic sealing film 143 is an inorganic film and can be constituted by, for example, a silicon oxide film, a silicon nitride film, or a silicon oxynitride film, or a layered film thereof. The inorganic film is formed by CVD, for example. The organic film 142 is a transparent organic film having a flattening effect, and can be made of a coatable organic material such as acrylic, for example.

The function film 150 is a film with at least one function selected from the group consisting of an optical compensation function, a touch sensor function, and a protection function, for example.

### Light-Emitting Element

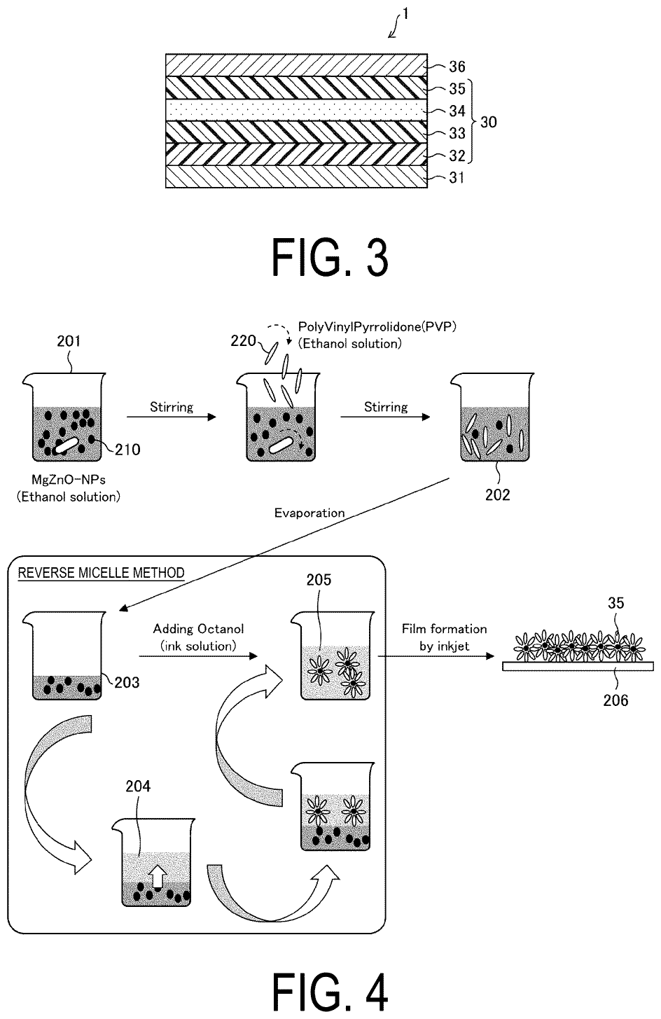

FIG. 3 schematically illustrates an example of a configuration of a light-emitting element 1 according to an embodiment of the disclosure. The light-emitting element 1 is a QLED. As illustrated in FIG. 3, the light-emitting element 1 includes a first electrode 31, the second electrode 36, and a light-emitting function layer 30 that is any one of the light-emitting function layer 30R, the light-emitting function layer 30G, and the light-emitting function layer 30B, and that is provided between the first electrode 31 and the second electrode. Note that as illustrated in FIG. 2, the light-emitting element 1 is formed on the thin film transistor layer 130, the thin film transistor layer 130 is formed on the barrier layer 120, and the barrier layer 120 is formed on the substrate 110. The bank 40 is disposed on the thin film transistor layer 130 and partitions the light-emitting function layer 30 in plan view.

The bank 40 is disposed on the thin film transistor layer 130 and is made of a transparent resin. Examples of the transparent resin include polyimide and an acrylic resin. The bank 40 can be prepared by applying an ink containing the transparent resin to a plane and then patterning the ink by photolithography.

The light-emitting function layer 30 includes a hole injection layer 32, a hole transport layer 33, a light-emitting layer 34 that is any one of a red light-emitting layer, a green light-emitting layer, and a blue light-emitting layer, and an electron transport layer 35, and these layers are layered in this order from the thin film transistor layer 130 side.

In the present embodiment, the first electrode 31 is also referred to as an anode. The first electrode 31 has electrical conductivity and has optical characteristics of, for example, reflecting a part of visible light and transmitting the rest thereof. The first electrode 31 contains both an electrode material that reflects visible light and an electrode material that transmits visible light.

Examples of the electrode material that reflects visible light include metal materials such as Al, Mg, Li and Ag, alloys of these metal materials, layered bodies (for example, ITO/Ag/ITO) of the above metal materials or the above alloys and transparent metal oxides (for example, indium tin oxide (ITO), indium zinc oxide, and indium gallium zinc oxide).

Examples of the electrode material that transmits visible light include a transparent metal oxide, a thin film made of a metal material such as Al and Ag, and a nano wire made of the metal material.

The first electrode 31 can be prepared by a general electrode forming method. Examples of the method for preparing the first electrode 31 include physical vapor deposition (PVD) and chemical vapor deposition (CVD). Examples of the physical vapor deposition include vacuum vapor deposition, sputtering, electron beam (EB) vapor deposition, and ion plating. Examples of the method for patterning the first electrode 31 include photolithography and an ink-jet method.

The hole injection layer (HIL) 32 is made of a hole injection material capable of stabilizing injection of positive holes into the light-emitting layer 34. Examples of the hole injection material include Poly(3,4-Ethylene DiOxyThiophene):PolyStyrene Sulfonic acid (PEDOT:PSS), NiO, and CuSCN.

The hole transport layer (HTL) 33 is made of a hole transport material capable of stabilizing transport of positive holes into the light-emitting layer 34. Examples of the hole transport material include poly[(9,9-dioctylfluorenyl-2,7-diyl)-co-(4,4′-(N-(4-sec-butylphenyl))diphenylamine)] (TFB), and poly[N,N′-bis(4-butylphenyl)-N,N′-bis(phenyl)-benzidine] (poly-TPD).

The light-emitting layer (EML) 34 is constituted by quantum dots (QDs). Note that the QD is a dot having a maximum width equal to or less than 100 nm. A shape of the QD may be a spherical three-dimensional shape (circular cross-sectional shape), or may be, for example, a polygonal cross-sectional shape, a rod-shaped three-dimensional shape, a branch-shaped three-dimensional shape, or a three-dimensional shape having unevenness on the surface thereof, or a combination thereof.

The QD may have, for example, a core structure, or may be a core/shell structure, a core/shell/shell structure, or a core/shell with continuously varying ratio structure. The QD may be provided with a ligand. When the QD has the core structure, the ligand may be provided on a surface of the core, and when the QD has the shell structure, the ligand may be provided on a surface of the shell structure.

Examples of a material constituting the core structure of the QD include Si and C in a case of a mono-component system. Examples of the material include CdSe, CdS, CdTe, InP, GaP, InN, ZnSe, ZnS, and ZnTe in a case of a binary system. Examples of the material include CdSeTe, GalnP, and ZnSeTe in a case of a ternary system. Examples of the material include AIGS in a case of a quaternary system.

Examples of a material constituting the shell structure of the QD include CdS, CdTe, CdSe, ZnS, ZnSe, and ZnTe in a case of a binary system. Examples of the material include CdSSe, CdTeSe, CdSTe, ZnSSe, ZnSTe, ZnTeSe, and AIP in a case of a ternary system.

The electron transport layer (ETL) 35 is made of an electron transport material capable of stabilizing transport of electrons into the light-emitting layer 34. In the present embodiment, the electron transport layer 35 is constituted by MgZnO-PVP nanoparticles (MgZnO-PVP-NPs). The MgZnO-PVP-NP has a core structure of MgZnO as the electron transport material and a shell structure of PVP and has a nano-order particle diameter. The MgZnO-PVP-NP corresponds to the composite material nanoparticle described above. Examples of the electron transport material include nanoparticles containing one or more elements selected from the group consisting of Zn, Mg, Ti, Si, Sn, W, Ta, Ba, Zr, Al, Y, and Hf in addition to MgZnO.

In the present embodiment, the second electrode 36 is also referred to as a cathode. The second electrode 36 has, for example, electrical conductivity and transparency of visible light. Examples of the electrode material constituting the second electrode 36 include ITO and Ag NanoWires (NW). The second electrode 36 can be made of the electrode material described above for the first electrode 31, and can be prepared by the method described above for the first electrode 31 according to the electrode material. The second electrode 36 is formed on the entire surface of the light-emitting element 1 on a side opposite to the first electrode 31 with the light-emitting function layer 30 interposed therebetween, and covers the electron transport layer 35, the bank 40, and the thin film transistor layer 130.

In the light-emitting element 1, the electron transport layer 35 is formed in a uniform arrangement of the MgZnO-PVP-NPs. Therefore, the electron transport layer 35 exhibits a high electron transport function, and thus the light-emitting element 1 has high luminous efficiency.

### Method for Manufacturing Light-Emitting Element

According to an embodiment of the disclosure, a method for manufacturing a light-emitting element includes applying an ink containing composite material nanoparticles as an upper layer relative to a light-emitting layer and forming an electrical function layer. In the disclosure, the method for manufacturing the light-emitting element can be carried out by a typical method for manufacturing a light-emitting element including a light-emitting layer, except for including the applying and forming described above. Note that the “upper layer” means a layer formed in a process after that of the target layer (light-emitting layer).

The electrical function layer can be formed by applying the ink containing the composite material nanoparticles to a plane by an ink-jet method. Here, the “plane” is a semi-finished product of the light-emitting element to be applied with the ink, and is, for example, a product obtained by performing the process until forming the light-emitting layer for the above-described light-emitting element.

The ink contains the composite material nanoparticles, which are uniformly dispersed in an ink solvent. Since a solvent having appropriate wettability according to the plane is selected as the ink solvent, the ink in which the composite material nanoparticles are uniformly dispersed is uniformly applied onto the light-emitting layer in preparing the electrical function layer (the electron transport layer 35 in the light-emitting element 1 of FIG. 3) adjacent to the light-emitting layer. Thus, the uniform electrical function layer with the composite material nanoparticles is formed on the light-emitting layer.

### Ink

According to an embodiment of the disclosure, an ink is formed by dispersing composite material nanoparticles in a long-chain alcohol.

A content of the composite material nanoparticles in the ink may be an amount that can be applied to a plane by an ink-jet method, and may be, for example, 5 to 50 mg/mL.

The long-chain alcohol is appropriately selected from the viewpoint of having appropriate wettability for the surface of the plane to be applied with the ink. From such a viewpoint, the long-chain alcohol is preferably an alcohol having a main chain with 6 or more carbons. The number of carbons of the long-chain alcohol is preferably 8 or less and 4 or more from the viewpoint of other physical properties for an ink-jet ink, such as a viscosity, in addition to the wettability described above. One or more types of the long-chain alcohol may be used. Examples of the long-chain alcohol include 1-hexanol, 1-heptanol and 1-octanol.

The metal oxide nanoparticles in the composite material nanoparticles are selected from the viewpoint of exhibiting desired characteristics for the electrical function layer. Examples of the metal oxide nanoparticles in the ink include MgZnO and NiO nanoparticles as described above.

Note that the content of the PVP in the ink may be an amount equal to or larger than an amount of the PVP supported on the surfaces of the metal oxide nanoparticles in the composite material nanoparticles. For example, the content of the PVP in the ink may be equal to or more than 20 parts by mass relative to 100 parts by mass of the composite material nanoparticles in the ink. The content of the PVP in the ink is preferably equal to or more than 50 parts by mass relative to 100 parts by mass of the composite material nanoparticles in the ink from viewpoint of sufficiently densely arranging the metal oxide nanoparticles in the electrical function layer.

The content of the PVP in the ink can be analyzed with an analyzer such as a high performance liquid chromatograph (HPLC) and a gel permeation chromatograph (GPC).

In addition, the fact that the composite material nanoparticles are uniformly dispersed in the ink can be confirmed by uniformly emitting light when the ink is irradiated with ultraviolet rays as described in Example, which will be described later. In the ink of the disclosure, the composite material nanoparticles are stably dispersed. As for the dispersion stability, the fact that the ink is a uniform dispersion liquid can be confirmed based on the fact that no precipitate is observed even after centrifugal separation at a room temperature (of 20 to 25° C.) and 4000 rpm for 5 minutes, and a Tyndall phenomenon is observed when laser light is irradiated.

The ink of the disclosure may further contain another component other than the composite material nanoparticles and the long-chain alcohol as long as the effects of the disclosure are obtained. The other component is appropriately used within a range in which an effect of the other component can be obtained together with the effect of the disclosure. Examples of the other component include amine, carboxide and phosphonyl.

### Method for Manufacturing Ink

In the disclosure, the ink can be manufactured by a method including dispersing metal oxide nanoparticles in ethanol and thus preparing a first liquid (first liquid preparation), dispersing polyvinyl pyrrolidone in the first liquid and thus preparing a second liquid (second liquid preparation), evaporating the ethanol from the second liquid and thus forming a solid containing metal oxide nanoparticles and polyvinyl pyrrolidone (solid formation), and adding a long-chain alcohol to the solid, bringing the long-chain alcohol into contact with the solid, diffusing the metal oxide nanoparticles together with the polyvinyl pyrrolidone in the long-chain alcohol, and thus manufacturing an ink (ink manufacture).

### First Liquid Preparation

The first liquid preparation is a process of preparing an ethanol dispersion liquid of metal oxide nanoparticles. In the first liquid preparation, a first liquid in which metal oxide nanoparticles are dispersed in ethanol is prepared.

In adding and dispersing the metal oxide nanoparticles in the ethanol, a dispersing apparatus capable of sufficiently stirring the ethanol to disperse the metal oxide nanoparticles as nanoparticles in the ethanol can be used. The dispersing apparatus may be a known stirring apparatus such as a magnetic stirrer.

The content of the metal oxide nanoparticles in the first liquid can be appropriately determined based on the desired content of the composite material nanoparticles in the ink to be manufactured. The content of the ethanol in the first liquid may be an amount that is sufficient to disperse the metal oxide nanoparticles and that is capable of dissolving PVP. From these viewpoints, the content of the metal oxide nanoparticles in the first liquid is preferably 5 to 50 mg/mL.

In the first liquid preparation, from the viewpoint of stably dispersing the metal oxide nanoparticles in the ethanol, ligands may be coordinated to the metal oxide nanoparticles during the first liquid preparation. As the ligands, one or more types of ligands may be used. Examples of the ligands include BF₄⁻, BF₆⁻, F⁻ and Cl⁻. The ligands can be coordinated to the metal oxide nanoparticles in the ethanol dispersion liquid by adding a ligand material corresponding to the content of the metal oxide nanoparticles in the ethanol dispersion liquid to the ethanol serving as a dispersion medium. Examples of the ligand material include a chlorine anion, a bromine anion, an iodine anion, a tetrafluoroborate anion, a tetrafluorophosphate anion, a hexafluorophosphate anion and a trifluoromethanesulfonylimide anion.

### Second Liquid Preparation

The second liquid preparation is a process of dissolving PVP in the ethanol dispersion liquid of the metal oxide nanoparticles. In the second liquid preparation, PVP is added, dispersed, and dissolved in the first liquid to prepare a second liquid in which the metal oxide nanoparticles are dispersed in an ethanol solution of the PVP. Like the first liquid preparation, the second liquid preparation can also be performed by using a known stirring apparatus.

The content of the PVP in the second liquid is preferably equal to or more than 50 parts by mass relative to 100 parts by mass of the metal oxide nanoparticles in the second liquid from the viewpoint of bringing the metal oxide nanoparticles into sufficient contact with a solid of the PVP regarding the solid, which will be described later. The content of the PVP in the second liquid is preferably equal to or less than 90 parts by mass relative to 100 parts by mass of the metal oxide nanoparticles in the second liquid from the viewpoint of causing the PVP to substantially contribute to generation of the composite material nanoparticles in the ink manufacture, which will be described below, and suppressing generation of excess PVP.

### Solid Formation

The solid formation is a process of distilling the ethanol away from the second liquid and producing a solid containing the metal oxide nanoparticles and the PVP. The solid is a solid object in a state where the PVP is attached to the surfaces of the metal oxide nanoparticles, and may be a solid in which the PVP has a continuous phase and the metal oxide nanoparticles have a dispersed phase.

### Ink Manufacture

The ink manufacture is a process of bringing the above-described solid into contact with a long-chain alcohol, and eluting the PVP from the solid into the long-chain alcohol and releasing the metal oxide nanoparticles in a dispersed state into the long-chain alcohol. The ink manufacture can be carried out by pouring the long-chain alcohol into a container accommodating the solid and causing the solid immersed in the long-chain alcohol to stand at a room temperature (of 20 to 25° C.).

Since the ink manufactured in the ink manufacture does not form a precipitate even by centrifugal separation under the above-described conditions, it is considered that the metal oxide nanoparticles are dispersed as nanoparticles. In addition, since the Tyndall phenomenon is observed by using the laser light as described above, it is considered that the ink is a uniform dispersion liquid and the dispersed metal oxide nanoparticles are accompanied with the PVP. Furthermore, since uniform dispersion is observed both before and after the centrifugal separation, it is considered that the PVP contributes to stabilizing the dispersion of the metal oxide nanoparticles. From the above, it is considered that the PVP is supported on the surfaces of the metal oxide nanoparticles and covers the surfaces thereof.

A mechanism of dispersion in the ink manufacture is considered as follows. The PVP dissolves in the long-chain alcohol and also attracts the metal oxide nanoparticles due to interactions such as hydrogen bonding. Since affinity of the metal oxide nanoparticles for the long-chain alcohol is lower than that for the PVP, the PVP is coordinated on the surfaces of the metal oxide nanoparticles exposed to the long-chain alcohol due to the elution of the PVP. In this way, the PVP is attached to the surfaces of the metal oxide nanoparticles released into the long-chain alcohol due to the elution of the PVP. The particles in which the PVP is coordinated on the surfaces of the metal oxide nanoparticles correspond to the “composite material nanoparticles” described above.

It is considered that such attachment of the PVP to the surfaces of the metal oxide nanoparticles is caused by coordination of the PVP to the metal oxide nanoparticles or support of the PVP by the metal oxide nanoparticles. It is considered that the metal oxide nanoparticles are stably dispersed in the long-chain alcohol in the ink manufacture by a mechanism the same as or similar to that of a reverse micelle method.

### Other Processes

The method for manufacturing the ink may further include processes other than the processes described above as long as the effects of the disclosure can be obtained. Examples of other processes include a process of adding the long-chain alcohol and adjusting a concentration of the ink, and a process of adding a new long-chain alcohol to a part or all of the long-chain alcohol in the ink produced in the ink manufacture. In the former process, the concentration of the metal oxide nanoparticles in the ink and the concentration of the PVP dissolved in the ink can be lowered. The latter process makes it possible to adjust only the concentration of the PVP dissolved in the ink. In the latter process, the long-chain alcohol to be added may be appropriately selected as long as the composite material nanoparticles are dispersed, and may be the same as or different from the long-chain alcohol poured into the container in the ink manufacture.

Specific Aspect from Manufacture of Ink to Manufacture of Light-Emitting Element

Hereinafter, a specific aspect of the manufacture of the ink and the manufacture of the light-emitting element in the disclosure will be described with reference to FIG. 4 to FIG. 6. In this aspect, the metal oxide nanoparticles are nanoparticles of MgZnO (MgZnO NPs) and the long-chain alcohol is 1-octanol. Further, the plane is a semi-finished product in which the substrate 110, the barrier layer 120, the thin film transistor layer 130, the bank 40, the first electrode 31, the hole injection layer 32, the hole transport layer 33, and the light-emitting layer of the light-emitting element 1 illustrated in FIG. 3 are produced. Furthermore, the electrical function layer is the electron transport layer 35, and the ink is an ink for the electron transport layer 35.

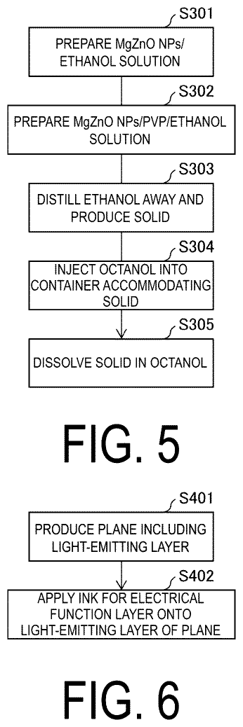

FIG. 4 is a diagram schematically illustrating an example of a manufacturing process from an ink to an electrical function layer according to the embodiment of the disclosure. FIG. 5 is a flowchart illustrating an example of a process procedure of the method for manufacturing the ink according to the embodiment of the disclosure. FIG. 6 is a flowchart illustrating an example of a distinctive process procedure of the method for manufacturing the light-emitting element according to the embodiment of the disclosure.

As illustrated in FIG. 4 and FIG. 5, MgZnO NPs 210 are added into ethanol in a beaker and dispersed by stirring to prepare a MgZnO NPs/ethanol solution 201 in which the MgZnO NPs are dispersed in the ethanol (step S301). The MgZnO NPs/ethanol solution 201 corresponds to the first liquid described above.

Next, PVP 220 is added to the MgZnO NPs/ethanol solution and dispersed by stirring to prepare a MgZnO NPs/PVP/ethanol solution 202 in which the PVP is dissolved in the ethanol in which the MgZnO NPs are dispersed (step S302). The MgZnO NPs/PVP/ethanol solution 202 corresponds to the second liquid described above.

Next, the ethanol is distilled away from the MgZnO NPs/PVP/ethanol solution 202 under a reduced pressure to produce a solid 203 in which the MgZnO NPs are dispersed in a PVP matrix (step S303).

Next, 1-octanol 204 is injected into the beaker accommodating the solid (step S304). The 1-octanol 204 corresponds to the long-chain alcohol described above.

Next, the solid is allowed to stand in a state of being immersed in the 1-octanol to dissolve the solid in the 1-octanol (step S305). In this step, the PVP in the solid is dissolved, and accordingly, the MgZnO NPs in the solid are released into the 1-octanol in a state in which the PVP is supported on the surfaces thereof. The released MgZnO/PVP NPs together with the PVP correspond to the composite material nanoparticles described above. In this way, an ink 205 in which the MgZnO/PVP NPs are stably dispersed in the 1-octanol is produced.

On the other hand, in the manufacture of the light-emitting element, as illustrated in FIG. 6, a plane 206 including a light-emitting layer is produced (step S401). The plane 206 is the light-emitting layer 34 in which an upper surface of the light-emitting layer is exposed.

Next, as illustrated in FIG. 6, the ink 205 is applied onto the light-emitting layer of the plane 206 by an ink-jet method (step S402). Since the ink 205 contains the MgZnO/PVP NPs uniformly and stably dispersed, an electron transport layer constituted by the MgZnO/PVP NPs is formed on the light-emitting layer.

Then, a cathode is formed on the entire surface of the electron transport layer, thereby manufacturing the light-emitting element as illustrated in FIG. 3.

### Main Actions and Effects

As for the ink of the disclosure, the metal oxide nanoparticles, as the composite material nanoparticles described above, are included in the ink. Therefore, according to the ink of the disclosure, the metal oxide nanoparticles can be stably dispersed in the ink.

In a known ink for ink-jet coating that forms an ETL, MgZnO NPs are difficult to disperse in octanol, which is an ink solvent, and phase separation from the ink solvent occurs. This is considered to be because MgZnO NPs are usually provided with ligands from the viewpoint of improving dispersibility, and the ligands have insufficient interaction with the ink solvent.

In the method for manufacturing the ink according to the embodiment of the disclosure, the ethanol is distilled away under the reduced pressure from the second liquid obtained by dissolving the PVP in the first liquid in which the metal oxide nanoparticles are dispersed in the ethanol. Then, the obtained solid (the mixture of the metal oxide nanoparticles and the PVP) is brought into contact with the long-chain alcohol serving as the ink solvent at a room temperature to obtain the ink in which the metal oxide nanoparticles (composite material nanoparticles) supporting the PVP on the surfaces thereof are stably dispersed in the long-chain alcohol.

In the ink of the disclosure, the metal oxide nanoparticles serving as the composite material nanoparticles can be uniformly and stably dispersed in the ink solvent, resulting in preventing occurrence of coating unevenness of the ink in preparing the electrical function layer. This prevents functional deterioration of the electrical function layer caused by the coating unevenness. The effect of preventing such coating unevenness is more remarkably exhibited in applying an ink to a large substrate by an ink-jet method or applying an ink by using a coater that is mainly used to apply an ink to a large substrate.

Additionally, in the ETL prepared by using the ink, the MgZnO NPs are uniformly distributed, and the PVP functions as a binder. Therefore, according to the embodiment of the disclosure, dispersibility of the metal oxide nanoparticles in the ink is improved, an electronic defect caused by a distribution of the metal oxide nanoparticles in the electrical function layer is suppressed, and an effect of improving a desired function in the electrical function layer is obtained. Thus, according to the embodiment of the disclosure, luminous efficiency of the light-emitting element can be improved, and occurrence of luminance unevenness between the light-emitting elements can be prevented.

### Modified Example

In the light-emitting element of the disclosure, the electrical function layer may be a layer adjacent to the light-emitting layer in the layering direction, or may be disposed with another layer interposed between the electrical function layer and the light-emitting layer.

In the light-emitting element of the disclosure, when the electrical function layer includes a plurality of types of layers, the electrical function layer manufactured with the ink of the disclosure may be only one layer among the layers of the electrical function layer, or may be each of the plurality of layers.

In the method for manufacturing the light-emitting element according to the disclosure, the electrical function layer manufactured by applying the ink may be an electrical function layer positioned above the light-emitting layer when the ink is applied. The coating surface to which the ink of the disclosure is applied to manufacture the electrical function layer may be a surface of the light-emitting layer, or may be a surface of a layer other than the light-emitting layer, such as another electrical function layer.

The light-emitting element 1 of each color described above has a normally layered structure, but in the display device of the disclosure, the light-emitting element may have an inversely layered structure. The light-emitting element having the inversely layered structure includes a first electrode serving as a cathode, a second electrode serving as an anode and facing the first electrode, and a light-emitting function layer disposed between both the electrodes and overlapping both the electrodes. In addition, the light-emitting function layer includes an electron injection layer, an electron transport layer, a light-emitting layer, a hole transport layer, and a hole injection layer that are layered in this order from the first electrode side. In the light-emitting element of the disclosure, in any of the normally layered structure and the inversely layered structure, one or more layers among the layers of the electrical function layer, for example, among the hole injection layer, the hole transport layer, the electron transport layer, and the electron injection layer may be appropriately omitted as long as the effect of the disclosure is obtained.

In the display device of the disclosure, the electrical function layers of the respective colors may be the same or different. For any layer in the electrical function layer, for example, the hole injection layers of the respective colors may be made of the same material, or may be made of materials different from each other, or only the hole injection layer of one or some colors may be made of a different material.

In the display device according to the disclosure, as described above, all of the light-emitting elements of the respective colors may be elements having the same light-emitting mechanism (all of the light-emitting elements are QLEDs in the embodiment described above), but the light-emitting element of one or some colors may be an element having a different light-emitting mechanism. For example, one or some of the red light-emitting element, the green light-emitting element, and the blue light-emitting element may be a QLED, and the remaining one or some of the light-emitting elements may be an OLED. In this case, the method for manufacturing the light-emitting element of each color can be appropriately selected according to the type of the light-emitting element of each color. For example, the light-emitting layer of the light-emitting element that is the QLED may be prepared by a coating method or an ink-jet method, and the light-emitting layer of the light-emitting element that is the OLED may be prepared by vapor deposition.

In the display device of the disclosure, the light-emitting element of each color may be a top-emission type as in the previous embodiment, or may be a bottom-emitting type. In the case of the light-emitting element having the normally layered structure, a top-emission light-emitting element can be formed by forming a first electrode serving as an anode with an electrode material that reflects visible light and forming a second electrode serving as a cathode with an electrode material that transmits visible light. In addition, a bottom-emission light-emitting element can be formed by forming a first electrode serving as an anode with an electrode material that transmits visible light and forming a second electrode serving as a cathode with an electrode material that reflects visible light. In the case of the inversely layered structure, a top-emission light-emitting element can be formed by forming a first electrode serving as a cathode with an electrode material that reflects visible light and forming a second electrode serving as an anode with an electrode material that transmits visible light. In addition, a bottom-emission light-emitting element can be formed by forming a first electrode serving as a cathode with an electrode material that transmits visible light and forming a second electrode serving as an anode with an electrode material that reflects visible light.

### Supplement

As is clear from the above description, a light-emitting element according to a first aspect of the disclosure includes a light-emitting layer and an electrical function layer overlapping the light-emitting layer, and the electrical function layer contains nanoparticles constituted by metal oxide nanoparticles and polyvinyl pyrrolidone. In the first aspect, the electrical function layer is a layer containing the nanoparticles constituted by the metal oxide nanoparticles and the PVP, which fabricates the light-emitting element including the electrical function layer in which the metal oxide nanoparticles are uniformly present.

In a light-emitting element according to a second aspect of the disclosure, in the first aspect, the electrical function layer is an electron transport layer, and the metal oxide nanoparticles are nanoparticles of an n-type semiconductor. The second aspect is more effective from the viewpoint of enhancing luminous efficiency of the light-emitting element by improving a function of the electron transport layer.

In a light-emitting element according to a third aspect of the disclosure, in the second aspect, the n-type semiconductor is MgZnO. The third aspect is more effective from the viewpoint of enhancing the luminous efficiency of the light-emitting element by improving the function of the electron transport layer.

In a light-emitting element according to a fourth aspect of the disclosure, in any one of the first to third aspects, the electrical function layer is a hole function layer, and the metal oxide nanoparticles are nanoparticles of a p-type semiconductor. The fourth aspect is more effective from the viewpoint of enhancing the luminous efficiency of the light-emitting element by improving the function of the hole transport layer.

In a light-emitting element according to a fifth aspect of the disclosure, in the fourth aspect, the p-type semiconductor is NiO. The fifth aspect is more effective from the viewpoint of enhancing the luminous efficiency of the light-emitting element by improving the function of the hole transport layer.

A sixth aspect of the disclosure is a method for manufacturing a light-emitting element including applying an ink containing nanoparticles constituted by metal oxide nanoparticles and polyvinyl pyrrolidone and thus forming an electrical function layer as an upper layer of a light-emitting layer. In the sixth aspect, since the electrical function layer is formed by applying the ink, the light-emitting element including the electrical function layer in which the metal oxide nanoparticles are uniformly present can be fabricated.

In a method for manufacturing a light-emitting element according to a seventh aspect of the disclosure, in the sixth aspect, the ink is applied to a plane by an ink-jet method, and thus the electrical function layer is formed. The seventh aspect is more effective from the viewpoint of enhancing the function of the electrical function layer made of the ink.

An eighth aspect of the disclosure is an ink containing particles constituted by metal oxide nanoparticles and polyvinyl pyrrolidone, the particles being dispersed in a long-chain alcohol. In the eighth aspect, since the nanoparticles constituted by the metal oxide nanoparticles and the PVP are stably dispersed in the ink, the light-emitting element including the electrical function layer in which the metal oxide nanoparticles are uniformly present by using the ink as a material for the electrical function layer can be fabricated.

In an ink according to a ninth aspect of the disclosure, in the eighth aspect, the long-chain alcohol is an alcohol including a main chain with 6 or more carbons. The ninth aspect is even more effective from the viewpoint of enhancing coatability of the ink on the plane.

In an ink according to a tenth aspect of the disclosure, in the eighth or ninth aspect, the metal oxide nanoparticles are nanoparticles of MgZnO or NiO. The tenth aspect is even more effective from the viewpoint of fabricating an electron transport layer or a hole function layer having a high function among layers of the electrical function layer formed by applying an ink.

An eleventh aspect of the disclosure is a method for manufacturing an ink including dispersing metal oxide nanoparticles in ethanol and thus preparing a first liquid, dispersing polyvinyl pyrrolidone in the first liquid and thus preparing a second liquid, evaporating the ethanol from the second liquid and thus forming a solid containing the metal oxide nanoparticles and the polyvinyl pyrrolidone, and bringing a long-chain alcohol into contact with the solid, diffusing the metal oxide nanoparticles together with the polyvinyl pyrrolidone in the long-chain alcohol, and thus manufacturing the ink according to any one of the eighth to tenth aspects. In the eleventh aspect, since the electrical function layer is manufactured by using the ink in which the nanoparticles constituted by the metal oxide nanoparticles and the PVP are stably dispersed, the electrical function layer in which the metal oxide nanoparticles are uniformly present can be manufactured by using the ink, and thus the light-emitting element including such an electrical function layer can be fabricated.

In a method for manufacturing an ink according to a twelfth aspect of the disclosure, in the eleventh aspect, ligands are coordinated to the metal oxide nanoparticles in the preparing of the first liquid. The twelfth aspect is even more effective from the viewpoint of enhancing the dispersibility of the metal oxide nanoparticles in the manufacturing of the ink.

The disclosure is not limited to the embodiments described above, and various modifications may be implemented within a range not departing from the scope of the claims. Embodiments obtained by appropriately combining technical approaches disclosed in each of the different embodiments also fall within the scope of the technology of the disclosure. Furthermore, novel technical features can be formed by combining the technical approaches disclosed in each of the embodiments.

According to the configurations of the disclosure, more stable and higher image quality is achieved in a display device with low power consumption, and contribution to achievement of sustainable development targets (SDGs) related to education, welfare, life, and industry is expected.

### Example

Example of the disclosure will be described below.

### Ink Preparation

An ethanol dispersion liquid of MgZnO NPs in which nanoparticles of MgZnO (MgZnO NPs) are dispersed in ethanol at a concentration of 20 mg/mL is prepared. The MgZnO NPs contain ligands for enhancing dispersibility in the ethanol, and the ligands are coordinated to the MgZnO NPs in the ethanol dispersion liquid. As a result, in the ethanol dispersion liquid, the MgZnO NPs are dispersed in the ethanol in a state of nanoparticles.

On the other hand, an ethanol solution of Poly Vinyl Pyrrolidone (PVP) is prepared.

The ethanol dispersion liquid of the MgZnO NPs is mixed with the ethanol solution of the PVP so that an amount of the PVP is 2 parts by mass relative to 1 parts by mass of the MgZnO NPs, and the MgZnO NPs are uniformly dispersed to prepare a MgZnO NPs-PVP mixed solution 1. Similarly, the ethanol dispersion liquid of the MgZnO NPs is mixed with the ethanol solution of the PVP so that the amount of the PVP is 4 parts by mass relative to 3 parts by mass of the MgZnO NPs, and the MgZnO NPs are uniformly dispersed to prepare a MgZnO NPs-PVP mixed solution 2.

Next, the ethanol is evaporated from the MgZnO NPs-PVP mixed solution 1 by an evaporator to obtain a solid content 1 that is a mixture of the MgZnO NPs and the PVP.

Next, at a room temperature, 1-octanol (hereinafter also simply referred to as “octanol”), which serves as an ink solvent, is added to a container containing the solid content 1, and the solid content 1 is immersed in the octanol. In this state, the solid content 1 immersed in the octanol is allowed to stand at a room temperature (25° C.) for 1 hour or more to gradually disperse the solid content 1 in a liquid phase. An ink 1 in which the solid content 1 is dispersed in the octanol is obtained.

In the process of dispersing the solid content 1 in the octanol, the MgZnO NPs are not dispersed by itself in the octanol. Therefore, it is considered that the PVP is coordinated to the surfaces of the MgZnO NPs, and the MgZnO NPs with the PVP on the surfaces thereof are dispersed in the octanol. That is, the ink 1, which is a dispersion liquid of the MgZnO NPs coordinated with the PVP on the surface thereof, is generated by a reverse micelle method.

Further, an ink 2 is prepared in a similar manner except that a MgZnO NPs-PVP mixed solution 2 is used instead of the MgZnO NPs-PVP mixed solution 1.

Further, the MgZnO NPs are directly added to the octanol and dispersed by irradiation with ultrasonic waves for 10 minutes or more to prepare an ink C1 for comparison.

### Evaluation of Ink

### (1) Dispersion Stability

By using a centrifuge, the ink 1 was centrifuged at a room temperature at 4000 rpm for 5 minutes. Then, presence or absence of a precipitate was visually checked, and uniformity of dispersion was visually checked by UV irradiation. The ink 1 was not phase-separated by centrifugal separation under the above conditions, and no precipitate was observed. In addition, when the UV was irradiated, a uniform white color was exhibited. Thus, it was confirmed that in the ink 1, the MgZnO NPs were dispersed as stable nanoparticles without phase separation.

When the ink C1 was subjected to centrifugal separation under the same conditions, it was confirmed that the ink C1 was phase-separated by centrifugal separation under the above conditions, and precipitates of aggregated MgZnO NPs adhered to an inner wall of the container in the form of stripes along a depth direction of the container at portions of the inner wall of the container corresponding to outer sides in a rotational direction of the centrifugal separation.

### (2) Ink Characteristics

A contact angle, a boiling point, a viscosity, and a surface tension on a quantum dot (QD) layer of the octanol, which was a dispersion medium of the ink 1, were determined. As the QD layer, a layer obtained by applying an ink containing QDs onto a hole transport layer HTL by an ink-jet method up to a thickness of 10 to 60 nm (preferably 20 to 40 nm) was used. The contact angle was measured by DropMaster DMs-400 (manufactured by Kyowa Interface Science Co., Ltd.). The viscosity was measured by a rheometer AR-2000ex (TA Instruments). Additionally, the surface tension was measured by a surface tensiometer CBVP-Z (manufactured by FACE). The results are shown in Table 1.

TABLE 1

| | Contact angle | Boiling | Viscosity | Surface |
|---|---|---|---|---|
| Solvent | (°) on QD | point (° C.) | (cP) | tension (mN/m) |
| 1-octanol | 17.1 | 195 | 7.3 | 27.5 |

Next, physical properties of the ink 1 shown in Table 2 were determined. A density of the ink 1 was determined from measurement values of a volume and a weight of the ink 1. A nozzle diameter is a nozzle diameter of an ink-jet head “KM1024i series (manufactured by Konica Minolta, Inc.)” of an ink-jet evaluation device used for ink-jet evaluation of the ink 1. A fluid velocity is an ejection velocity of the ink in the evaluation device having the nozzle diameter, and is a velocity of droplets of 0.5 mm from a tip of the ink-jet head. As the viscosity and the surface tension, numerical values of the ink solvent (1-octanol) were adopted because a concentration of a functional material in the ink 1 was sufficiently low.

In addition, “Re” in Table 2 is a Reynolds number of the ink, and was obtained from the following Equation (1). “We” in Table 2 is a Weber number of the ink, and was obtained from the following Equation (2). “Z” in Table 2 is the inverse number of an Ohnesorge number in the ink, and was obtained from the following Equation (3). In the following Equations, “v” represents the ejection velocity of the ink, “r” represents the droplet diameter of the ink, “ρ” represents the density of the ink, “η” represents the viscosity of the ink, and “γ” represents the surface tension of the ink.

$$R e = v \cdot r \cdot p / η \qquad ( 1 )$$

$$We = {v}^{2} r \cdot ρ / γ \qquad ( 2 )$$

$$Z = R e / {( We )}^{1 / 2} \qquad ( 3 )$$

TABLE 2

| | |
|---|---|
| Density (kg/m³) | 8.24E+02 |
| Nozzle diameter (m) | 2.50E−05 |
| Fluid velocity (m/s) | 5.00E+00 |
| Viscosity (Pa · s) | 7.30E−03 |
| Surface tension (N/m) | 2.75E−02 |
| Re | 1.41E+01 |
| We | 1.87E+01 |
| Z | 3.26E+00 |

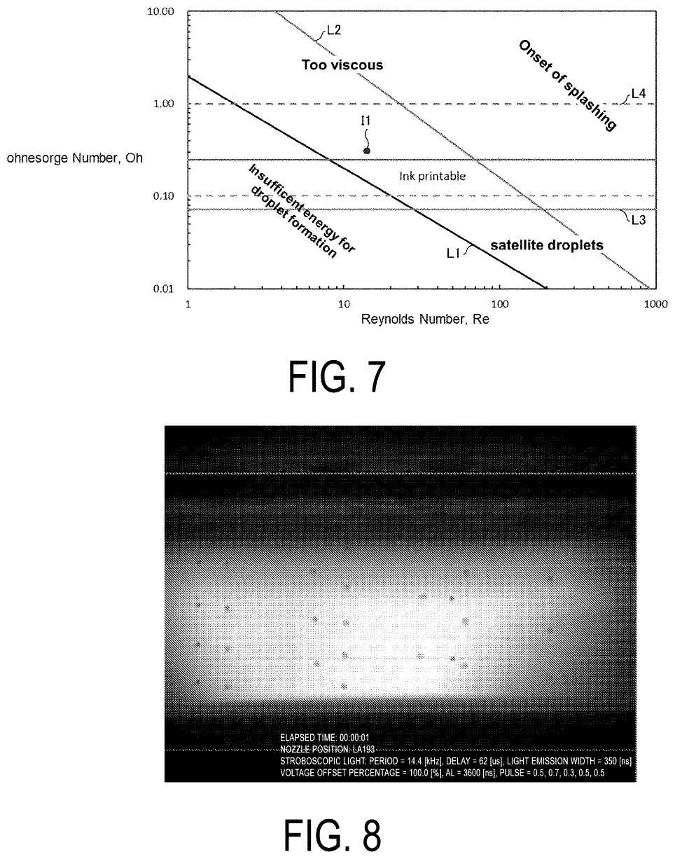

In addition, FIG. 7 illustrates coatability of the ink at coordinates with the Reynolds number and the Ohnesorge number serving as axes. A region surrounded by straight lines L1 to L4 in FIG. 7 is an “ink-printable” region, and an ink positioned in the region has coatability that can be adopted to ink-jet printing. A region below the straight line L1 in FIG. 7 is a region with an “energy insufficient for droplet formation”, and in the region, there is a tendency that ink droplets are not formed due to energy shortage in ink-jet printing. A region above the straight line L2 in FIG. 7 is a “splash-generating” region, and in the region, ink droplets tend to splash in ink-jet printing. A region below the straight line L3 in FIG. 7 is a “satellite droplet” region, and in the region, satellite droplets tend to be generated in ink-jet printing. A region above the straight line L4 in FIG. 7 is a “too-viscous” region, and in the region, the ink tends to be too viscous to be adopted to ink-jet printing.

A point I1 in FIG. 7 represents a position of the ink 1 in FIG. 7. The ink 1 is positioned in the region surrounded by the straight lines L1 to L4, and thus has suitability as an ink for ink-jet printing.

FIG. 8 is a photograph illustrating an image of droplets of the ink 1 flying in ink-jet printing. As illustrated in FIG. 8, it was confirmed that the droplets of the ink 1 discharged by an ink-jet method flied in stable shapes, and thus the ink 1 is favorably discharged by an ink-jet device.

In addition, the ink 1 has substantially the same physical properties (for example, the contact angle and the surface tension) as those of 1-octanol serving as an ink solvent. 1-octanol has wettability with respect to QDs as shown in Table 1.

From the above, it can be seen that the ink 1 can be suitably used for manufacture of an electrical function layer (such as an electron transport layer) adjacent to a light-emitting layer of each of an QLED and an OLED in application by an ink-jet method.

### INDUSTRIAL APPLICABILITY

The disclosure is applicable to a light-emitting element in which a layer is formed by applying an ink.

1-5. (canceled)

6. A method for manufacturing a light-emitting element, the method comprising:
applying an ink including nanoparticles constituted by metal oxide nanoparticles and polyvinyl pyrrolidone and thus forming an electrical function layer as an upper layer of a light-emitting layer, wherein
the ink is applied to a plane by an ink-jet method, and thus the electrical function layer is formed.

7. (canceled)

8. An ink comprising:
particles constituted by metal oxide nanoparticles and polyvinyl pyrrolidone, the particles being dispersed in a long-chain alcohol.

9. The ink according to claim 8,
wherein the long-chain alcohol is an alcohol including a main chain with 6 or more carbons.

10. The ink according to claim 8,
wherein the metal oxide nanoparticles are nanoparticles of MgZnO or NiO.

11. A method for manufacturing an ink, the method comprising:
dispersing metal oxide nanoparticles in ethanol and thus preparing a first liquid;
dispersing polyvinyl pyrrolidone in the first liquid and thus preparing a second liquid; and
evaporating the ethanol from the second liquid and thus forming a solid including the metal oxide nanoparticles and the polyvinyl pyrrolidone; and
bringing a long-chain alcohol into contact with the solid, diffusing the metal oxide nanoparticles together with the polyvinyl pyrrolidone in the long-chain alcohol, and thus manufacturing the ink according to claim 8.

12. The method for manufacturing the ink according to claim 11,
wherein ligands are coordinated to the metal oxide nanoparticles in the preparing of the first liquid.

13. (canceled)
